(19) United States
(12) Patent Application Publication
(10) Pub. No.: US 2014/0015633 A1
(43) Pub. Date: Jan. 16, 2014

(54) PRESSURE-SENSITIVE SWITCH

(71) Applicant: Panasonic Corporation, Osaka (JP)

(72) Inventors: RYO NAKAE, Osaka (JP); TAMOTSU YAMAMOTO, Hyogo (JP)

(73) Assignee: Panasonic Corporation, Osaka (JP)

(21) Appl. No.: 14/025,829

(22) Filed: Sep. 13, 2013

Related U.S. Application Data
(63) Continuation of application No. PCT/JP2012/001337, filed on Feb. 28, 2012.

(30) Foreign Application Priority Data
Mar. 25, 2011 (JP) 2011-067240

(51) Int. Cl. H03K 17/96

(52) U.S. Cl. CPC H03K 17/9625
USPC 338/47

(57) ABSTRACT

A pressure-sensitive switch includes a pressing member, a flexible base member under the pressing member, a resistance layer on an underside of the base member, an electrode group, a third electrode, and a resistance element. The electrode group includes first and second electrodes and confronts the base member so as to be brought into contact with the resistance layer when the pressing member is pressed. The third electrode is disposed apart from the electrode group and confronts the base member same as the electrode group. The resistance element is connected to the first and second electrodes in series therebetween. The first electrode is located nearer a pressing center of the pressing member than the second electrode.

### BACKGROUND

1. Technical Field

The technical field relates to a pressure-sensitive switch to be used chiefly for operating a variety of electronic devices.

2. Background Art

Recently, electronic devices such as portable telephones and terminals of car navigation systems have become more sophisticated and diversified. Accordingly, there is a need for a pressure-sensitive switch that functions diversely and operates reliably.

A conventional pressure-sensitive switch is described hereinafter with reference to FIG. 7 and FIG. 8. FIG. 7 is an exploded perspective view of the conventional pressure-sensitive switch and FIG. 8 is a sectional view of the same.

Pressure-sensitive switch 20 includes pressure-sensitive conductive sheet 5, electrode-pair 15, and pressing member 16. Conductive sheet 5 is formed of base member 1, low-resistive layer 2, high-resistive layer 3, and spacer 4.

Flexible base member 1 is made of polyethylene-terephthalate or the like. Low-resistive layer 2 and high-resistive layer 3 are formed on an underside of base member 1 by a screen printing method. Annular spacer 4 is pasted on an underside of high-resistive layer 3.

Low-resistive layer 2 has a sheet resistance ranging from 50Ω/sq. to 30 kΩ/sq., and is made of phenol in which carbon powder is dispersed.

High-resistive layer 3 has a sheet resistance falling within a range from 50 kΩ/sq. to 5 MΩ/sq., and is made of phenol in which carbon powder is dispersed. Numerous spherical particles 6 are mixed in high-resistive layer 3 for providing the underside with peaks and valleys.

Electrode-pair 15 shaped like comb teeth is disposed on substrate 11 and includes electrodes 12A-12D and electrodes 13A-13C. Pressure-sensitive conductive sheet 5 is disposed above electrode-pair 15, which thus confronts high-resistive layer 3. A user presses pressing member 16, which then moves up and down. Pressing member 16 is disposed on an upper face of pressure-sensitive sheet 5.

Pressure-sensitive switch 20 is disposed on a front face of a housing of an electronic device such as a portable telephone and a terminal of car navigation system, and is used for moving a cursor (not shown) displayed on an LCD (not shown) of the device.

A press by the user onto an upper face of pressing member 16 of switch 20 allows electrodes 12A-12D and electrodes 13A-13C to be brought into contact with the underside of high-resistive layer 3. Since the underside of high-resistive layer 3 is provided with the peaks and the valleys, greater pressing force by the user results in a greater contact area between high-resistive layer 3 and electrodes 12A-12D, 13A-13C.

Electrodes 12A-12D are electrically connected to electrodes 13A-13C via high-resistive layer 3. A greater contact area between electrodes 12A-12D and layer 3, and a greater contact area between electrodes 13A-13C and layer 3 result in a smaller resistance value between electrodes 12A-12D and electrodes 13A-13C.

A press by the user onto the upper face of pressing member 16 of pressure-sensitive switch 20 changes the resistance value between electrodes 12A-12D and electrodes 13A-13C. This change in the resistance value changes an output voltage of electrode-pair 15 to a control circuit (not shown) of the electronic device. In response to the change in the voltage, the control circuit changes a speed of moving the cursor displayed on the LCD, for example.

### SUMMARY

A problem associated with the conventional pressure-sensitive switch 20 discussed above is difficulty in pressing member 16 with appropriate pressing force. A pressure-sensitive switch achieving an easy-operation is more preferable.

The pressure-sensitive switch of the present disclosure includes a pressing member to be pressed by a user, a flexible base member disposed under the pressing member, a resistance layer disposed on an underside of the base member, an electrode group, a third electrode, a resistance element, and first and second terminals. The electrode group is formed of multiple electrodes including first and second electrodes. The electrode group confronts the base member so as to be brought into contact with the resistance layer when the pressing member is pressed. The third electrode is disposed apart from the electrode group and confronts the base member so as to be brought into contact with the resistance layer when the pressing member is pressed. The resistance element is connected to the first and second electrodes in serial therebetween. The first terminal is connected to the second electrode and the resistance element therebetween. The second terminal is connected to the third electrode. The first electrode is located nearer a pressing center of the pressing member than the second electrode.

The pressure-sensitive conductive sheet of the present disclosure has a flexible base member and a resistance layer disposed on an underside of the base member. The resistance layer includes a low-resistive layer having a sheet resistance value ranging from 50Ω/sq. to 20 kΩ/sq., a medium-resistive layer having a sheet resistance value ranging from 20 kΩ/sq. to 80 kΩ/sq., and a high-resistive layer having a sheet resistance value ranging from 80 kΩ/sq. to 5 MΩ/sq.

### BRIEF DESCRIPTION OF DRAWINGS

FIG. 1 is an exploded perspective view of a pressure-sensitive switch in accordance with an embodiment.

FIG. 2 is a sectional view of the pressure-sensitive switch in accordance with the embodiment.

FIG. 3A is a sectional view of the pressure-sensitive switch in a state of being pressed in accordance with the embodiment.

FIG. 3B is a sectional view of the pressure-sensitive switch in a state of being pressed in accordance with the embodiment.

FIG. 4A is a circuit diagram of an electrode-pair used in the pressure-sensitive switch in accordance with the embodiment.

FIG. 4B is a circuit diagram illustrating operation of the electrode-pair used in the pressure-sensitive switch in accordance with the embodiment.

FIG. 5A shows a graph illustrating changes in resistance value in response to pressing force of the pressure-sensitive switch in accordance with the embodiment.

FIG. 5B shows a graph illustrating changes in voltage in response to the pressing force of the pressure-sensitive switch in accordance with the embodiment.

FIG. 6A is a top view of a substrate for illustrating a pattern of electrodes used in the pressure-sensitive switch in accordance with the embodiment.

FIG. 6B is a top view of a substrate for illustrating another pattern of electrodes used in the pressure-sensitive switch in accordance with the embodiment.

FIG. 6C is a top view of a substrate for illustrating still another pattern of electrodes used in the pressure-sensitive switch in accordance with the embodiment.

FIG. 7 is an exploded perspective view of a conventional pressure-sensitive switch.

FIG. 8 is a sectional view of the conventional pressure-sensitive switch.

### DETAIL DESCRIPTION

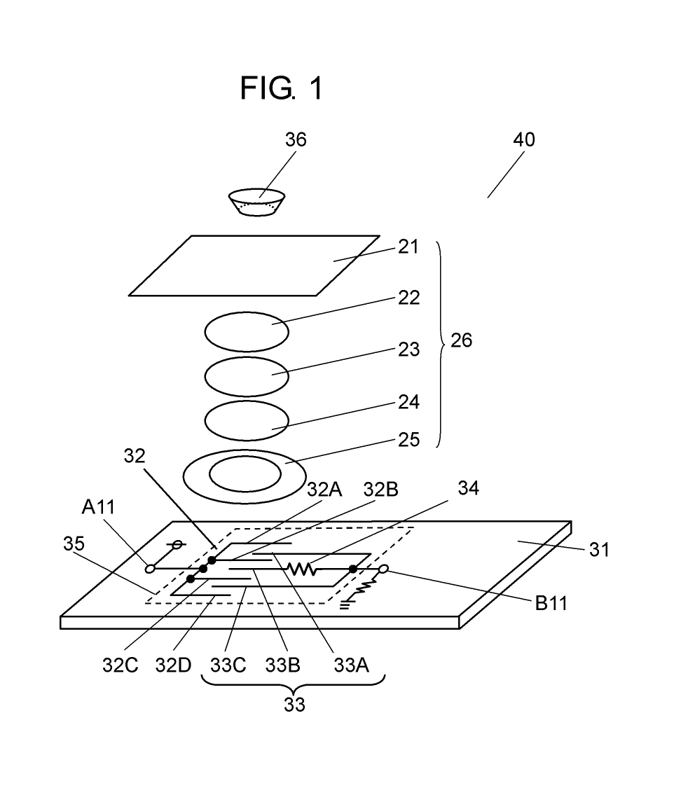

The pressure-sensitive switch in accordance with an exemplary embodiment is demonstrated hereinafter with reference to the accompanying drawings. Some drawings enlarge dimensions in part for the better understanding of the structures. FIG. 1 is an exploded perspective view of pressure-sensitive switch 40 in accordance with the embodiment.

Pressure-sensitive switch 40 in accordance with this embodiment has pressing member 36, base member 21, high-resistive layer 24, multiple electrodes 32A-32D and electrodes 33A-33C, and resistance element 34 connected to at least one of the foregoing electrodes.

Base member 21 is disposed under pressing member 36. High-resistive layer 24 works as a resistance layer and is printed on an underside of base member 21. Multiple electrodes 32A-32D are connected together in parallel and electrodes 33A-33C are also connected together in parallel. Those electrodes confront base member 21. Resistance element 34 is connected to at least one of the electrodes.

Electrode 33B which comes into contact with the resistance layer by a press onto the pressing member first among the multiple electrodes is electrically connected to other electrodes 33A and 33C in parallel via resistance element 34.

The structure discussed above allows the resistance value of electrode-pair 35 to vary rather moderately in response to changes in the pressing force applied to pressing member 36.

Pressure-sensitive switch 40 thus enables users of the electronic device (not shown) to operate the device with ease such as obtaining a desirable moving speed of a cursor (not shown) displayed on the device.

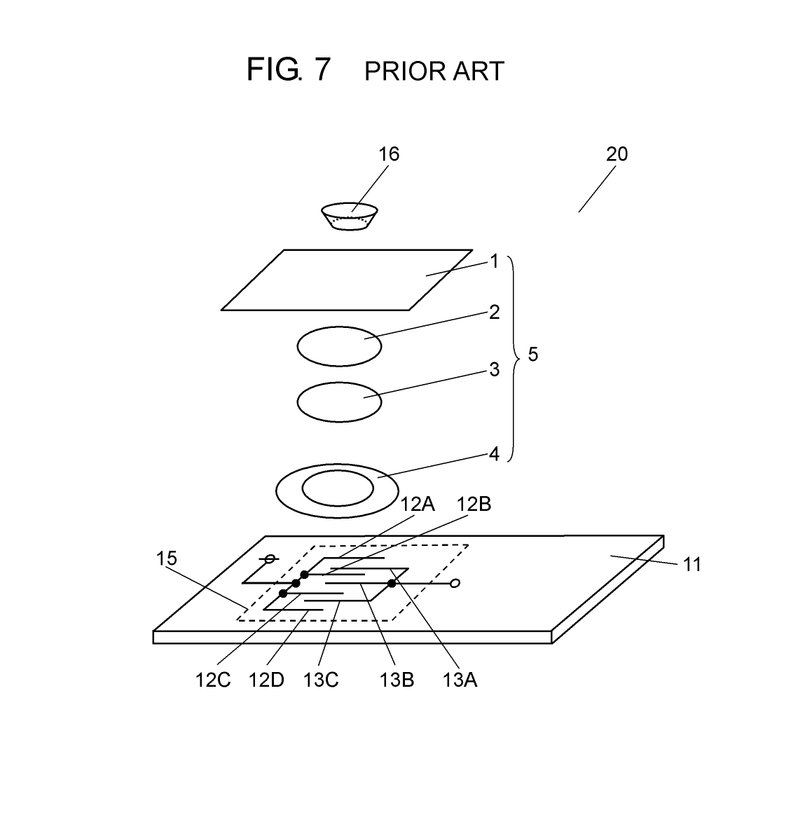

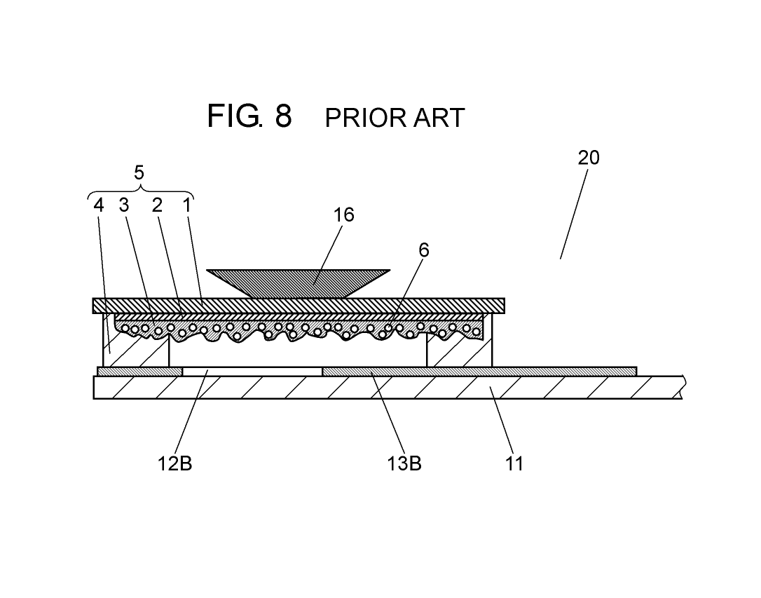

To be more specific, as shown in FIGS. 7 and 8, conventional pressure-sensitive switch 20 has extremely thin low-resistive layer 2 and extremely thin high-resistive layer 3. When pressing force, even it is weak one, is applied to the upper face of pressing member 16, the resistance value between electrodes 12A-12D and electrodes 13A-13C decreases instantly. As a result, it makes difficult for users to depress pressing member 16 with appropriate force, and this difficulty prevents the electronic device from being operated with ease.

The pressure-sensitive switch in accordance with this embodiment, on the other hand, enables electrode-pair 35 to change its resistance value rather moderately in response to the changes in the pressing force applied to pressing member 36. Electrode-pair 35 is formed of electrodes 32A-32D and electrodes 33A-33C.

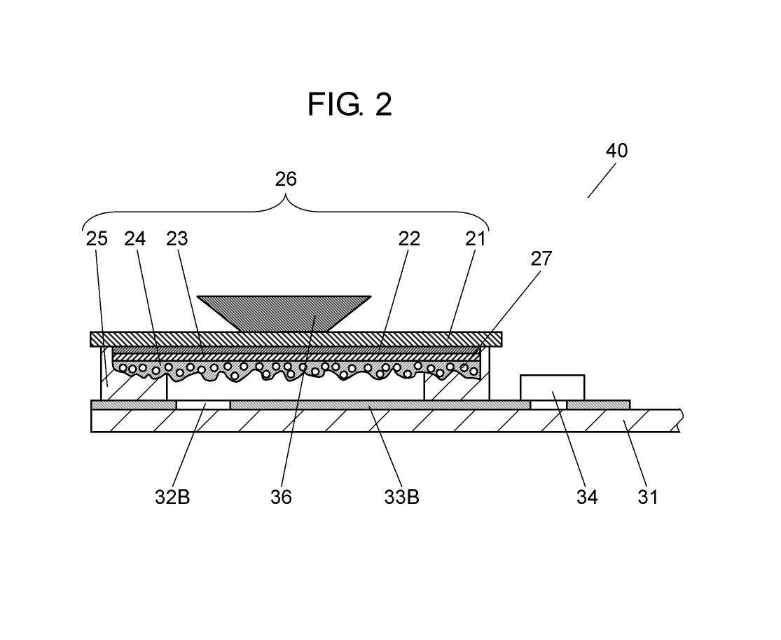

The embodiment is detailed more specifically hereinafter. FIG. 2 is a sectional view of pressure-sensitive switch 40 in accordance with one of the embodiments. As shown in FIG. 1 and FIG. 2, pressure-sensitive switch 40 includes pressure-sensitive conductive sheet 26, electrode-pair 35, and pressing member 36.

Pressure-sensitive sheet 26 includes base member 21, low-resistive layer 22, medium-resistive layer 23, high-resistive layer 24, and spacer 25.

Flexible base member 21 is made of polyethylene terephthalate or the like. Low-resistive layer 22, medium-resistive layer 23, and high-resistive layer 24 are formed on the underside of base member 21, and annular spacer 25 is pasted on the underside of high-resistive layer 24.

A resistance value of medium-resistive layer 23 is preferably between the sheet resistance value of high-resistive layer 24 and that of low-resistive layer 22, which has the lowest sheet resistance value among the three.

The sheet resistance values of the foregoing resistive layers preferably fall within the following ranges:
low-resistive layer 22: 50Ω/sq.-20 kΩ/sq.;
medium-resistive layer 23: 20 kΩ/sq.-80 kΩ/sq.; and
high-resistive layer 24: 80 kΩ/sq.-5 MΩ/sq.

Low-resistive layer 22, medium-resistive layer 23, and high-resistive layer 24 have thicknesses ranging from 1 μm to 50 μm, and they are formed by the screen printing method.

High-resistive layer 24, for instance, includes numerous spherical particles 27 mixed therein, and particles 27 provide the underside of high-resistive layer 24 with peaks and valleys.

Electrode-pair 35 in a comb-teeth shape is disposed on an upper face of substrate 31, and includes electrodes 32A-32D, electrodes 33A-33C, and resistance element 34.

Next, electrode-pair 35 is demonstrated hereinafter. Electrode-pair 35 is connected to a power supply at terminal A11 on the left side, and to the ground potential via a pull-down resistor at terminal B11 on the right side. Electrodes 32A-32D are connected to terminal A11, and electrodes 33A, 33C are connected to terminal B11. Electrode 33B is connected to terminal B11 via resistance element 34.

Pressure-sensitive conductive sheet 26 is disposed above electrode-pair 35, so that electrode-pair 35 confronts high-resistive layer 24. Pressing member 36, which is moved up and down by a user, is disposed on an upper face of pressure-sensitive sheet 26.

Pressure-sensitive switch 40 having the foregoing structure is disposed on a front face of the housing of an electronic device such as a portable telephone and a terminal of car navigation system. Switch 40 is used for moving a cursor (not shown) displayed on an LCD (not shown) of the electronic device.

When the user depresses the upper face of pressing member 36 of pressure-sensitive switch 40, upper faces of electrodes 12A-12D and upper faces of electrodes 13A-13C are brought into contact with the underside of high-resistive layer 24. Since the underside of high-resistive layer 24 is provided with the peaks and valleys, greater pressing force by the user will increase the contact area between high-resistive layer 24 and electrodes 32A-32D, 33A-33C.

Electrodes 32A-32D are electrically connected to electrodes 33A-33C via high-resistive layer 24. A greater contact area between electrodes 32A-32D and high-resistive layer 24, or a greater contact area between electrodes 33A-33C and high-resistive layer 24 will reduce the resistance value between electrodes 32A-32D and electrodes 33A-33C.

When the user depresses the upper face of pressing member 36 of pressure-sensitive switch 40, a change in the resistance value between high-resistive layer 24 and electrodes 32A-32D or between high-resistive layer 24 and electrodes 33A-33C varies a voltage supplied from electrode-pair 35 to the control circuit (not shown) of the electronic device. The control circuit varies a moving speed of the cursor displayed on the LCD based on this change in voltage.

When the user depresses the upper face of pressing member 36, the resistance value of electrode-pair 35 is changed and the voltage supplied from electrode-pair 35 is also changed. These changes are demonstrated hereinafter.

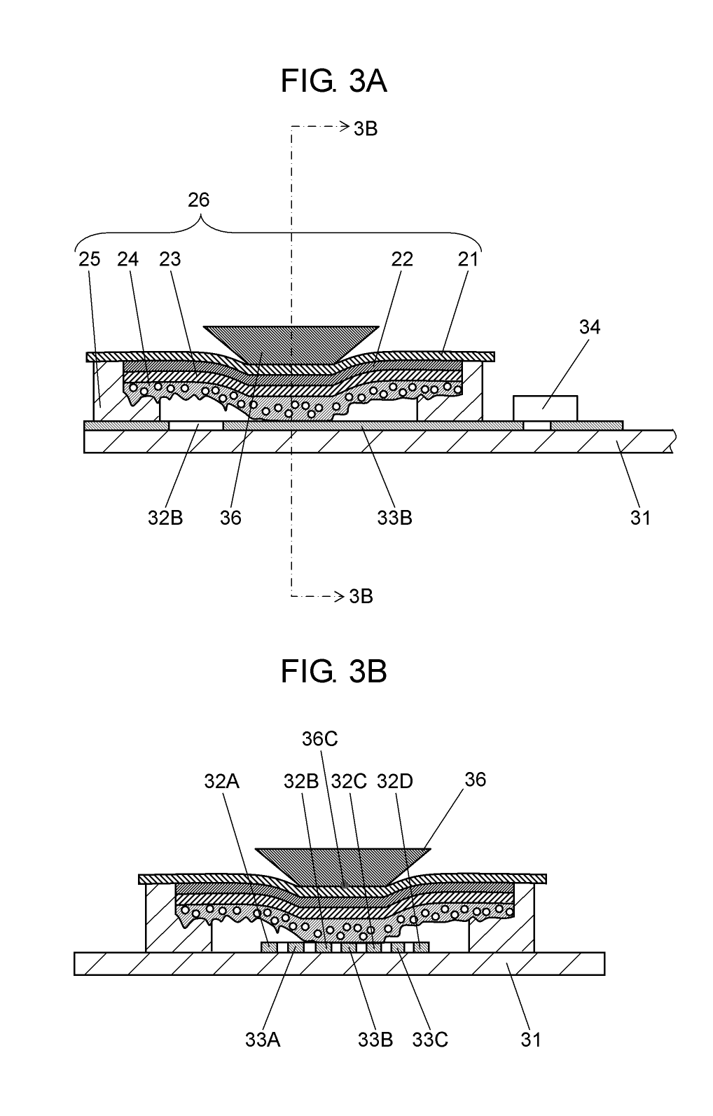

FIG. 3A is a sectional view of pressure-sensitive switch 40 cut along electrode 33B, and FIG. 3B is a sectional view of switch 40 cut along line 3B-3B in FIG. 3A.

When the user presses the upper face of pressing member 36, electrode 33B comes into contact with high-resistive layer 24 first among electrodes 33A-33C. As shown in FIG. 3B, high-resistive layer 24 is also brought into contact to electrodes 32B, 32C, so that electrode 33B is electrically connected to electrodes 32B, 32C via high-resistive layer 24.

An electric current thus flows from the power supply to the ground potential via electrodes 32B, 32C, 33B, low-resistive layer 22, medium-resistive layer 23, high-resistive layer 24, and resistance element 34. Terminal B11 resultantly outputs a voltage in response to the pressing force applied to pressing member 36.

When the user increases the pressing force applied to the upper face of pressing member 36, the high-resistive layer 24 is sequentially brought into contact with the electrodes 33A, 33C, 32A and 33C based upon which of the electrodes is closer to electrode 33B which first came into contact with the high-resistive layer 24.

Since high-resistive layer 24 has peaks and valleys on its underside, the stronger pressing force applied by the user to the upper face of pressing member 36 will increase the contact area between the respective electrodes and high-resistive layer 24. The stronger pressing force applied by the user will thus decrease the resistance value between the respective electrodes and high-resistive layer 24.

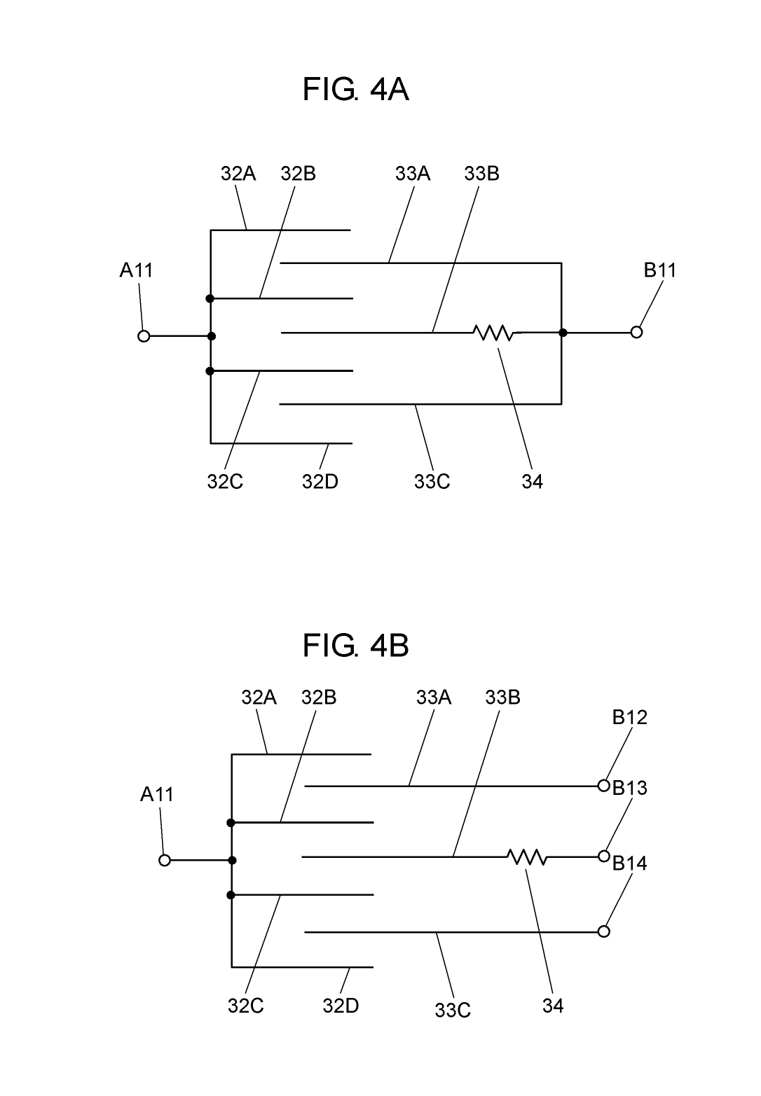

Changes in the resistance value and an output voltage of electrode pair 35 in response to the pressing force applied to the upper face of pressing member 36 are described hereinafter. FIG. 4A is a circuit diagram of electrode pair 35. FIG. 4B is a hypothetical diagram, in which electrodes 33A and 33C are separated from resistance element 34, for illustrating changes in the resistance values with respect to each one of electrodes 33A-33C.

In FIG. 4A, terminal A11 of electrode pair 35 is connected to the power supply, and terminal B11 that works as an output terminal of electrode pair 35 is connected to the ground potential via a pull-down resistance element. In FIG. 4B, terminals B12-B14 are output terminals related to electrode 33A, electrode 33B and resistance element 34, and electrode 33C.

The resistance value between terminals A11 and B11 shown in FIG. 4A is a composite value of the resistance value between terminals A11 and B12, the resistance value between terminals A11 and B13, and the resistance value between terminals A11 and B14 each shown in FIG. 4B.

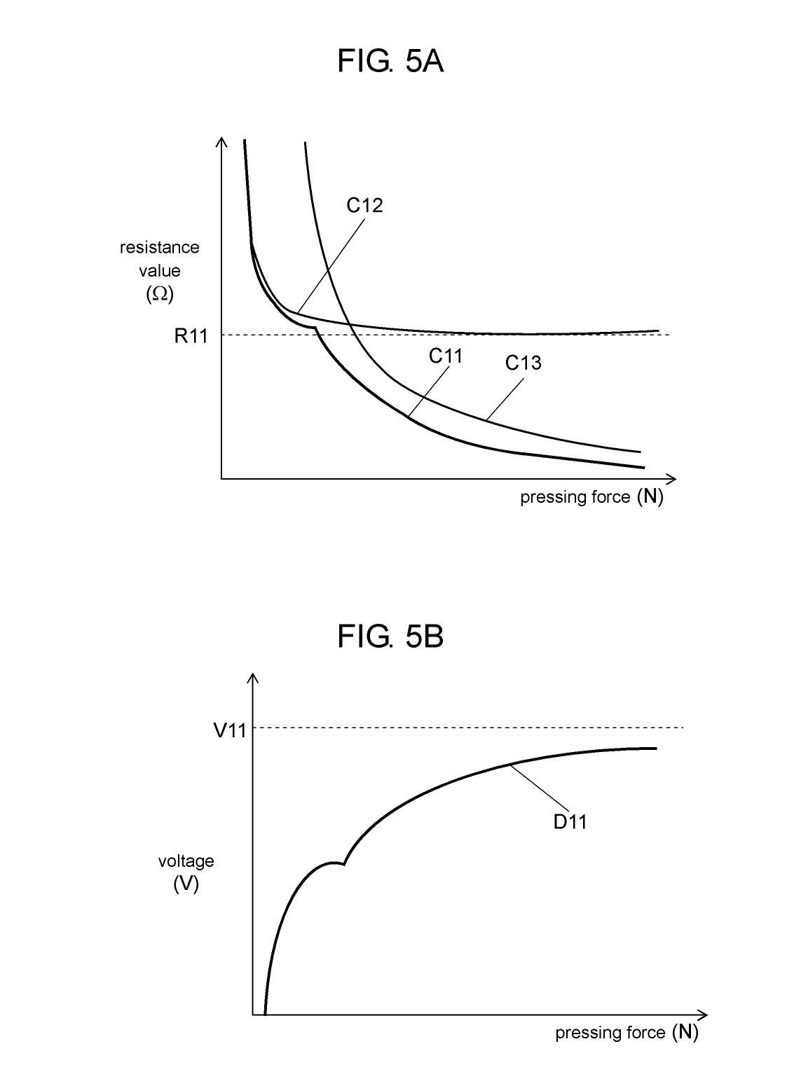

FIG. 5A shows variations in the foregoing resistance values in response to the pressing force applied by the user. FIG. 5B is a graph illustrating variations in the output voltage from terminal B11 in response to the pressing force by the user.

In FIG. 5A, curve C11 represents the resistance value between terminals A11 and B11. Curve C12 represents the resistance value between terminals A11 and B13. Curve C13 represents the resistance value between terminals A 11 and B12 and also represents the resistance value between terminals A11 and B14. Because the resistance value between terminals A11 and B12 is almost equal to that between terminals A 11 and B14, curve C13 represents both of these resistance values.

In FIG. 5B, curve D11 shows the output voltage from terminal B11. Curve D11 varies in inverse proportion to the change of curve C11 shown in FIG. 5A.

Since electrode 33B comes into contact with the underside of high-resistive layer 24 first among the electrodes, the contact area between them is great even if the pressing force is small. Curve C12 shown in FIG. 5A thus changes with small pressing force and converges to resistance value R11 that is a given resistance value of resistance element 34. Resistance value R11 preferably falls within the range from 10 kΩ to 10 MΩ, inclusive.

On the other hand, the resistance values of electrodes 33A, 33C decrease moderately as shown with curve C13 when the greater pressing force is applied.

As a result, the resistance value shown with curve C11 between terminal A11 and terminal B11 receives greater effect from curve C12 during an application of small pressing force; however, during an application of great pressing force, it receives greater effect from curve C13. As a whole, the resistance value shown with curve C11 changes rather moderately in response to the change in the pressing force.

As shown in FIG. 5B, curve D11 also changes rather moderately as a whole in response to the change in the pressing force similarly to the change of curve C11.

In other words, since resistance element 34 is connected to electrode 33B that comes into contact first with high-resistive layer 24, pressure-sensitive switch 40, as compared with conventional pressure-sensitive switch 20, can mitigate the effect given to the change in the resistance of electrode-pair 35 by a change in the contact resistance between high-resistive layer 24 and electrode 33B. This mechanism thus enables electrode-pair 35 to change its resistance value rather moderately in response to the change in the pressing force applied to pressing member 36.

As described above, electrodes 33A to 33C form electrode group 33 confronting base member 21 so as to be brought into contact with high-resistive layer 24 forming a resistance when pressing member 36 is pressed. Electrodes 32A to 32D forming comb-shaped electrode 32 are disposed apart from electrode group 33 and confront base member 21 so as to be brought into contact with high-resistive layer 24 when pressing member 36 is pressed. Resistance element 34 is connected to electrodes 33A and 33B in series therebetween. Terminal B11 is connected to electrode 33A and resistance element 34 therebetween. Terminal A11 is connected to comb-shaped electrode 32. As shown in FIG. 3B, electrode 33B is located nearer pressing center 36C of pressing member 36 than electrode 33A. According to this structure, electrodes 33B and 33A are brought into contact with high-resistive layer 24 sequentially and thus electrode-pair 35 changes its resistance value rather moderately in response to the change in the pressing force applied to pressing member 36.

Furthermore, electrode 33C is located farther from pressing center 36C of pressing member 36 than electrode 33A and connected to electrode 33A. Electrodes 33A to 33C are disposed in parallel to each other. According to this structure, electrodes 33B, 33A and 33C are brought into contact with high-resistive layer 24 sequentially in this order and thus electrode-pair 35 changes its resistance value rather moderately in response to the change in the pressing force applied to pressing member 36.

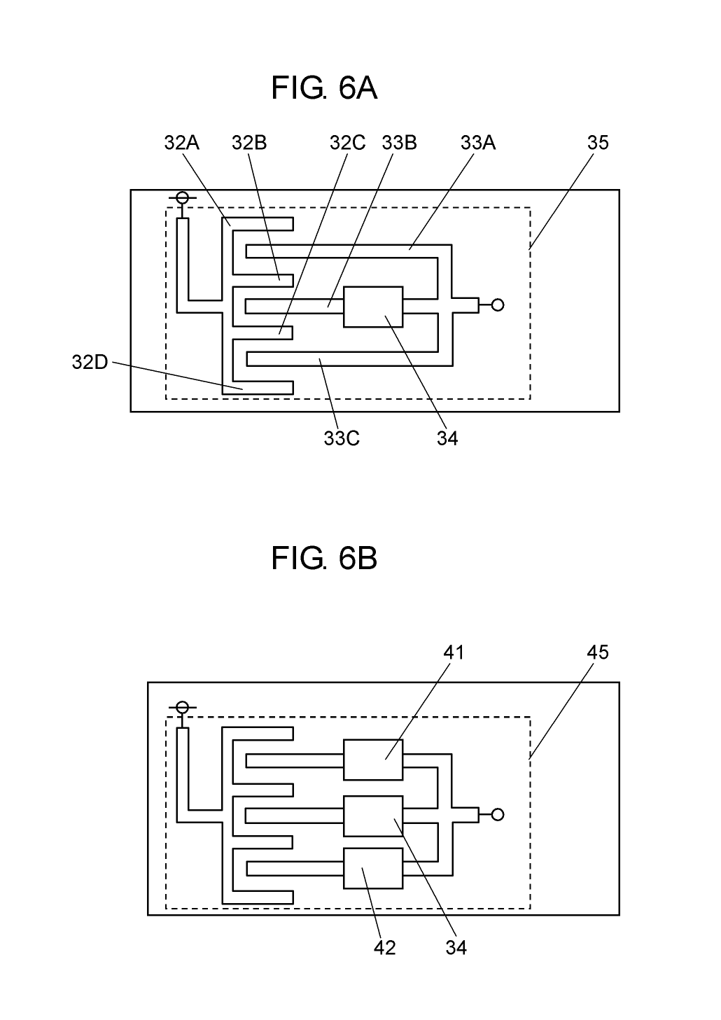

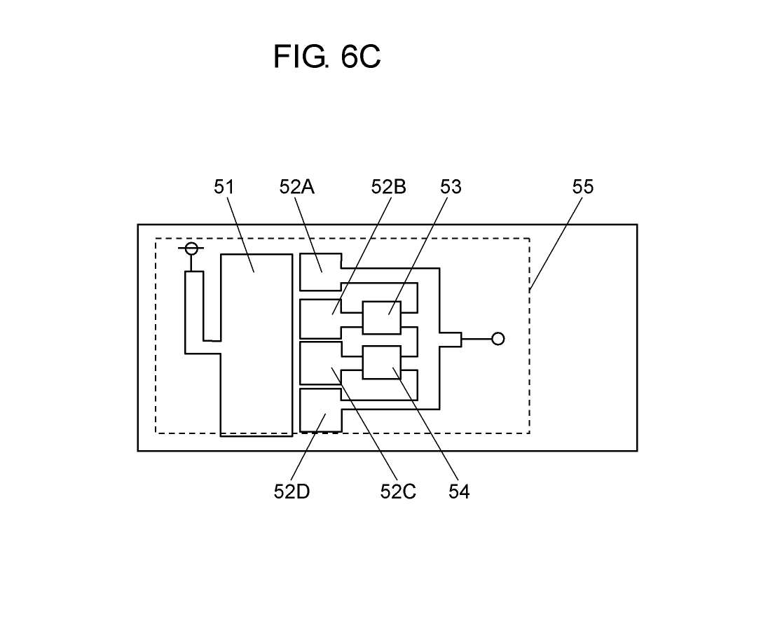

Next, examples of wiring patterns each of which employs electrode-pair 35, 45, or 55 are demonstrated hereinafter. FIG. 6A is a top view of substrate 31 for illustrating an example of wiring pattern of electrode-pair 35. FIG. 6B is a top view of substrate 31 for illustrating an example of wiring pattern of electrode-pair 45. FIG. 6C is a top view of substrate 31 for illustrating an example of wiring pattern of electrode-pair 55.

In FIG. 6A, the line width of electrodes 32A-32D, 33A-33C is 0.1 mm, and the respective electrodes are disposed at intervals of 0.1 mm, for instance, electrode 32A and electrode 33A are spaced 0.1 mm apart. Electrodes 32A-32D are disposed in parallel to each other at their contact sections with high-resistive layer 24. Electrodes 33A-33C are also disposed in parallel to each other at their contact sections with high-resistive layer 24.

Electrode 33B, which comes into contact with high-resistive layer 24 first among the electrodes, is electrically connected in parallel to electrodes 33A and 33C via resistance element 34.

Electrodes 33A-33C are disposed in parallel to each other at their contact sections with high-resistive layer 24 functioning as the resistance, and are brought into high-resistive contact to layer 24 sequentially starting from the electrode closest to the electrode that has come into first contact with high-resistive layer 24 by the pressing onto pressing member 36. This parallel placement of electrodes 33A-33C allows presuming with ease the given resistance value R11 of resistance element 34 based on the intervals between the respective electrodes.

Electrode-pair 45 shown in FIG. 6B is different from FIG. 6A in that resistance element 41 is connected to electrode 33A and resistance element 42 is connected to electrode 33C. In this case in that resistance elements 41 and 42 are respectively connected to electrodes 33A and 33C, it is acceptable that resistance elements 41 and 42 have smaller resistance values than that of resistance element 34.

Electrode 51 shown in FIG. 6C has a rectangle shape instead of the comb-teeth shape, and electrodes 52A-52D have different widths from each other. As FIG. 6C shows, the shape of the electrodes is not necessarily limited to the comb-teeth shape as long as multiple electrodes 52A-52D are electrically coupled together in parallel.

Electrodes 52B and 52C are connected electrically with resistance elements 53 and 54 respectively. The resistance element connected to one of the electrodes 52B and 52C, which first comes into contact with high-resistive layer 24 has a greater resistance value than the other resistance elements.

Low-resistive layer 22 or medium-resistive layer 23 is not necessarily required, but high-resistive layer 24 is needed. High-resistive layer 24 does not always need to be mixed with particles 27 as long as high-resistive layer 24 has peaks and valleys on its underside.

The pressure-sensitive switch of the present embodiments advantageously enables the user to operate with ease, and is useful for operating a variety of electronic devices.

What is claimed is:

1. A pressure-sensitive switch comprising:
a pressing member;
a flexible base member disposed under the pressing member;
a resistance layer disposed on an underside of the base member;
an electrode group formed of multiple electrodes including first and second electrodes, the electrode group confronting the base member so as to be brought into contact with the resistance layer when the pressing member is pressed;
a third electrode disposed apart from the electrode group and confronting the base member so as to be brought into contact with the resistance layer when the pressing member is pressed;
a resistance element connected to the first and second electrodes in series therebetween;
a first terminal connected to the second electrode and the resistance element therebetween; and
a second terminal connected to the third electrode,
wherein the first electrode is located nearer a pressing center of the pressing member than the second electrode.

2. The pressure-sensitive switch according to claim 1,
wherein the electrode group further includes a fourth electrode located farther from the pressing center of the pressing member than the second electrode and connected to the second electrode, and
the first, second and fourth electrodes are disposed in parallel to each other.

3. The pressure-sensitive switch according to claim 1,
wherein the resistance layer includes:
a low-resistive layer having a sheet resistance value ranging from 50Ω/sq. to 20 kΩ/sq.;
a medium-resistive layer having a sheet resistance value ranging from 20 kΩ/sq. to 80 kΩ/sq.; and
a high-resistive layer having a sheet resistance value ranging from 80 kΩ/sq. to 5 MΩ/sq.

4. The pressure-sensitive switch according to claim 3,
wherein the high-resistive layer includes spherical particles mixed therein, so that an underside of the high-resistive layer is provided with peaks and valleys.

5. The pressure-sensitive switch according to claim 1,
the resistance layer is printed on an underside of the base member.

6. A pressure-sensitive conductive sheet comprising:
a flexible base member; and
a resistance layer disposed on an underside of the base member,
wherein the resistance layer includes:
a low-resistive layer having a sheet resistance value ranging from 50Ω/sq. to 20 kΩ/sq.;
a medium-resistive layer having a sheet resistance value ranging from 20 kΩ/sq. to 80 kΩ/sq.; and
a high-resistive layer having a sheet resistance value ranging from 80 kΩ/sq. to 5 MΩ/sq.

7. The pressure-sensitive conductive sheet according to claim 6,
wherein the high-resistive layer includes spherical particles mixed therein, so that an underside of the high-resistive layer is provided with peaks and valleys.
